(19) United States
(12) Patent Application Publication
(10) Pub. No.: US 2007/0170596 A1
(43) Pub. Date: Jul. 26, 2007

(54) Flip-chip light emitting diode with high light-emitting efficiency

(76) Inventors: Way-Jze Wen, Lung Tan (TW); Yi-Fong Lin, Lung Tan (TW); Shyi-Ming Pan, Lung Tan (TW); Fen Ren Chien, Lung Tan (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/339,622

(22) Filed: Jan. 26, 2006

(51) Int. Cl. H01L 23/52

(52) U.S. Cl. 257/777

(57) ABSTRACT

A flip-chip light emitting diode with high light-emitting efficiency is disclosed. The LED includes a transparent conductive layer, an oxide layer, a reflective metal layer, a conductive layer, and a protective diffusion layer sequentially disposed over a p-type semiconductor layer. Thereby, light emitting from a light-emitting layer toward the p-type semiconductor layer is reflected and penetrating a transparent substrate and emitting outwards. Thus the problem of light shielded from the flip-chip type LED is solved and the light-emitting efficiency is improved. Furthermore, the present invention disposes the LED chip in a face-down orientation on a conductive substrate by flip-chip technology so as to enhance heat-dissipation efficiency of the LED.

### BACKGROUND OF THE INVENTION

The present invention relates to a light emitting diode, especially to a flip-chip light emitting diode with high light-emitting efficiency.

Due to large power consumption of conventional illumination devices caused by high power, people in industry or research institute in various countries are dedicated to developing illuminative components and the related design. Thus the light emitting diode (LED) is invented.

Refer to FIG. 1, it is a schematic drawing of conventional Light-emitting gallium nitride-based III-V group compound semiconductor device consisting of a gallium nitride buffer layer 2′, a n-type gallium nitride ohmic contact layer 3′, an indium gallium nitride (InGaN) emitting layer 4′, a p-type p-type aluminum gallium nitride cladding layer 5′, a p-type gallium nitride ohmic contact layer 6′ and a p-type transparent conductive metal layer 7′ in sequence. The epitaxy is growing on a sapphire substrate 1′. A positive electrode (anode electrode) 8′ is disposed on top of the p-type transparent conductive metal layer 7′ while a negative electrode 9′ is arranged on the n-type gallium nitride ohmic contact layer 3′. The positive electrode 8′ and the negative electrode 9′ are respectively connected with wires 10′, 11′ so as to conduct two electrodes of a conductive leadframe 12′.

In the above-mentioned LED, light emitted from the indium gallium nitride (InGaN) emitting layer 4′ is shielded by the positive electrode 8′ so that problems of smaller light-emitting area and unhomogeneous brightness are raised. In order to solve such problems, a flip-chip light emitting diode is developed. Refer to FIG. 2, a conventional flip-chip type LED is disclosed. As shown in figure, a LED chip is disposed in a face-down orientation to a base 15′ so that the positive electrode 8′ and the negative electrode 9′ of the LED chip attach on a first conductive area 13′ and a second conductive area 14′ of the base 15′ directly. Thus the light emitting from the light emitting layer 4′ doesn't pass through the positive electrode 8′, only penetrate the substrate 1′ such as sapphire. Thereby, the light-emitting area is increased.

Although the flip-chip light emitting diode in FIG. 2 solves the problem of the light from the light-emitting layer 4 being shielded by the positive electrode 8′. However, there is still part of the light from the flip-chip type LED emitting toward the first conductive area 13′, the second conductive area 14′ and the base 15′. Thus such kind of LED still can't emit light efficiently.

### SUMMARY OF THE INVENTION

Therefore it is a primary object of the present invention to provide a light emitting diode that is a flip-chip light emitting diode with high light-emitting efficiency so that the light from the light-emitting layer is reflected for preventing the light from being shielded.

It is another object of the present invention to provide a light emitting diode that the LED chip is disposed in a face-down orientation to the conductive substrate by the flip-chip technology so as to decrease thermal conductive distance of the LED, extend lifetime of the component, and further decrease the package volume.

In order to achieve above objects, a flip-chip light emitting diode with high light-emitting efficiency in accordance with the present invention includes a transparent conductive layer, an oxide layer, a reflective metal layer, a conductive layer, and a protective diffusion layer sequentially disposed over a p-type semiconductor layer so ass to reflect light from a light-emitting layer for enhancing light-emitting efficiency of the LED. Moreover, the present invention disposes the LED chip in a face-down orientation on a conductive substrate by flip-chip technology so as to enhance heat-dissipation efficiency of the LED. Further the lifetime of the LED is extended.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a schematic drawing of conventional light-emitting gallium nitride-based III-V group compound semiconductor device growing on a sapphire substrate;

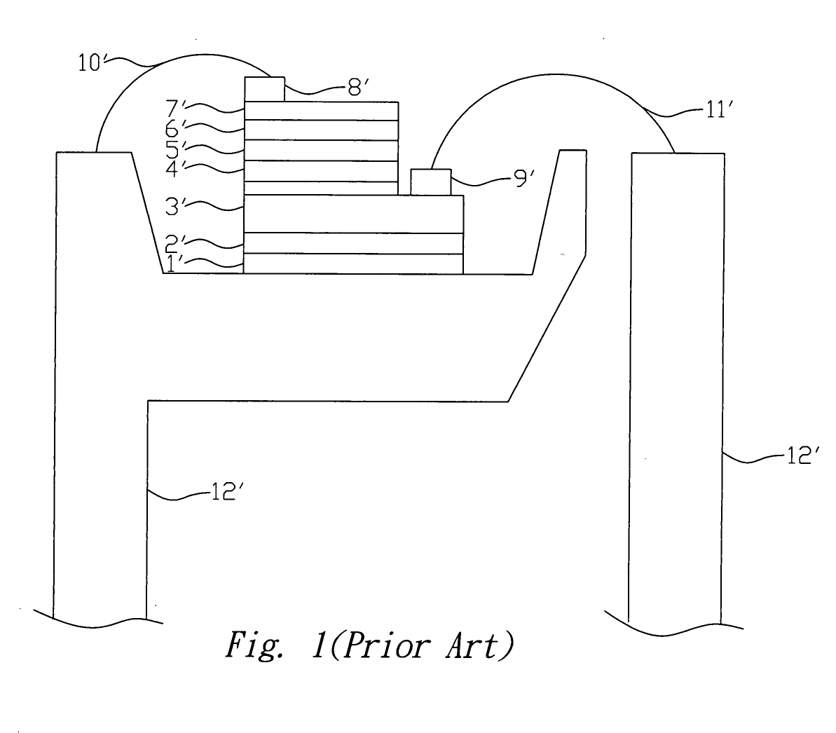

FIG. 2 is a schematic drawing of conventional flip-chip type LED;

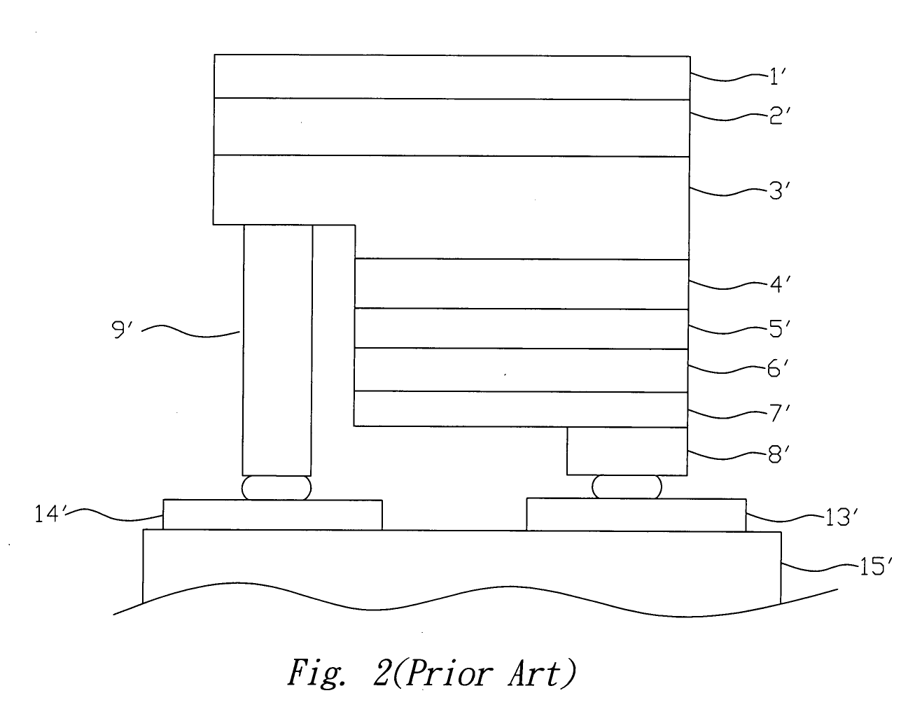

FIG. 3 is a schematic drawing of a flip-chip type LED with high light emitting efficiency in accordance with the present invention; and

FIG. 4 is a schematic drawing of a flip-chip type LED with high light emitting efficiency in accordance with the present invention.

### DETAILED DESCRIPTION OF THE PREFERRED EMBODIMENT

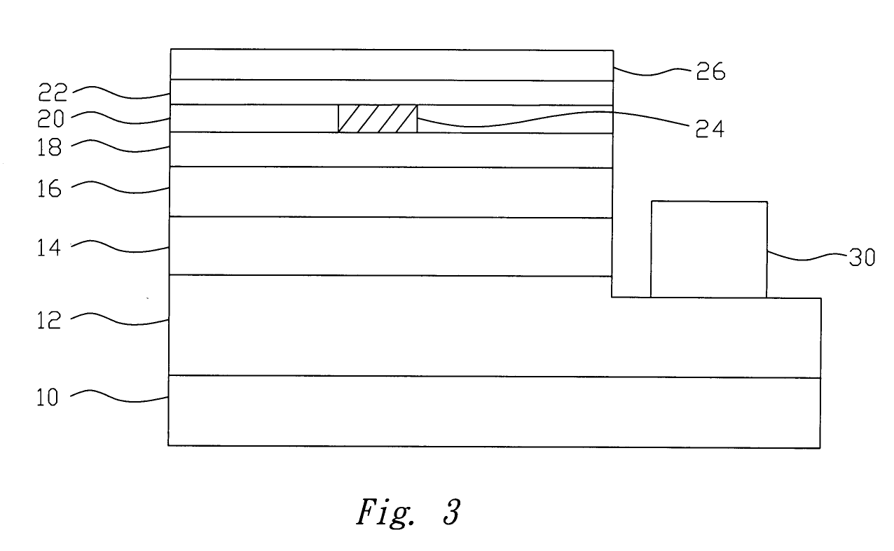

Refer to FIG. 3, a LED chip in accordance with the present invention is composed by a transparent substrate 10, a semiconductor stacked layer, a transparent conductive layer 18, an oxide layer 20, a reflective metal layer 22, a conductive layer 24, a protective diffusion layer 26 and a first electrode 30. The transparent substrate 10 is made from one of the following material: sapphire, silicon carbide (SiC), zinc oxide (ZnO), gallium phosphide (GaP), gallium arsenide (GaAs), or other material with high transparency.

Moreover, the semiconductor stacked layer, arranged over the transparent substrate 10, having a n-type semiconductor layer 12, a light emitting layer 14 and a p-type semiconductor layer 16 while the light emitting layer 14 is located between the n-type semiconductor layer 12 and the p-type semiconductor layer 16. The n-type semiconductor layer 12 is a n-GaN layer and the p-type semiconductor layer 16 is a p-GaN layer.

The light emitting layer 14 is made of InGaN/GaN multiple quantum well structure or III-V semiconductor quantum well structures while the semiconductor quantum well structures include AlₐIn_{b}Ga_{1-a-b}N/AlₓIn_{y}Ga_{1-x-y}N, wherein a,b≧0 ; 0≦a+b<1 ; x,y≧0 ; 0≦x+y<1 ; x>c>a.

A transparent conductive layer 18 is disposed over the p-type semiconductor layer 16 and having ohmic contact with the p-type semiconductor layer 16 for lower contact resistance. The transparent conductive layer 18 is made from indium oxide, tin oxide, indium molybdenum oxide, indium cerium oxide, zinc oxide, indium zinc oxide (IZO), magnesium zinc oxide, tin cadmium oxide, or indium tin oxide (ITO), nickel oxide, platinum, nickel-gold(Ni/Au), titanium nitride(TiN), tantalum nitride(TaN), CuAlO₂, LaCuOS, CuGaO₂, SrCu₂O₂, iridium oxide(lrO), rhodium oxide(RhO), or ruthenium oxide/gold(RuO/Au).

Moreover, after disposing the oxide layer 20 over the transparent conductive layer 18 and the reflective metal layer 22 over the oxide layer 20, the conductive layer 24 is arranged on the oxide layer 20 so as to make the transparent conductive layer 18 and the reflective metal layer 22 connect with each other electrically. The reflective metal layer 22 is made from gold(Au), aluminum(Al), silver(Ag), or rhodium(Rh). The oxide layer 20 is made from silicon dioxide(SiO₂), silicon nitride(Si₃N₄), silicon oxynitride (SiON), aluminum oxide (Al₂O₃), zinc oxide (ZnO), aluminum nitride (AIN) or beryllium nitride (BeN).

In this embodiment, the reflective metal layer 22 is made from silver or aluminum because their reflectivity is over 90% during the visible spectrum. This the LED in accordance with the present invention has higher reflectivity. However, the reflective metal layer 22 is made from materials with high diffusion coefficient that are easy to react with other metal. Therefore, the oxide layer 20 is arranged between the transparent conductive layer 18 and the reflective metal layer 22 as a barrier layer. Thereby, the LED in accordance with the present invention is able to stand higher temperature during manufacturing processes without influence of the reflective metal layer's 22 reflectivity. Furthermore, due to the barrier of the oxide layer 20, the ion migration of the reflective metal layer 22 is improved. Moreover, when the light emits from the light emitting layer 14, the light is reflected by the reflective metal layer 22 and then emits out the transparent substrate 10. Thus the problem that the light from the light emitting layer 14 is shielded by the positive electrode can be solved and further the light emitting efficiency of the flip-chip type LED is improved.

Next, the protective diffusion layer 26 is arranged over the reflective metal layer 22 for preventing the reflective metal layer 22 from reacting to other metals, with a function similar to that of the oxide layer 20. The protective diffusion layer 26 is made from Ti/Ni, Cr/Ni, TiN, TiW, wolfram, nickel, chromium, molybdenum, palladium, platinum, or combinations of above elements.

At last, the first electrode 30 is disposed on an area that the light emitting layer 14 is isolated from the n-type semiconductor layer 12 and the p-type semiconductor layer 16 is isolated from the light emitting layer 14. The first electrode 30 has good ohmic contact with the n-type semiconductor layer 12 for lower contact resistance and it is made from one of the following materials: Ti/Al, Ti/Al/Ti/Au, Ti/Al/Pt/Au, Ti/Al/Ni/Au, Ti/Al/Pd/Au, Ti/Al/Cr/Au, Ti/Al/Co/Au, Cr/Al/Cr/Au, Cr/Al/Pt/Au, Cr/Al/Pd/Au, Cr/Al/Ti/Au, Cr/Al/Co/Au, Cr/Al/Ni/Au, Pd/Al/Ti/Au, Pd/Al/Pt/Au, Pd/Al/Ni/Au, Pd/Al/Pd/Au, Pd/Al/Cr/Au, Pd/Al/Co/Au, Nd/Al/Pt/Au, Nd/Al/Ti/Au, Nd/Al/Ni/Au, Nd/Al/Cr/Au, Nd/Al/Co/Au, Hf/Al/Ti/Au, Hf/Al/Pt/Au, Hf/Al/Ni/Au, Hf/Al/Pd/Au, Hf/Al/Cr/Au, Hf/Al/Co/Au, Zr/Al/Ti/Au, Zr/Al/Pt/Au, Zr/Al/Ni/Au, Zr/Al/Pd/Au, Zr/Al/Cr/Au, Zr/Al/Co/Au, TiNₓ/Ti/Au, TiNₓ/Pt/Au, TiNₓ/Ni/Au, TiNₓ/Pd/Au, TiNₓ/Cr/Au, TiNₓ/Co/Au, TiWNₓ/Ti/Au, TiWNₓ/Pt/Au, TiWNₓ/Ni/Au, TiWNₓ/Pd/Au, TiWNₓ/Cr/Au, TiWNₓ/Co/Au, NiAl/Pt/Au, NiAl/Cr/Au, NiAl/Ni/Au, NiAl/Ti/Au, Ti/NiAl/Pt/Au, Ti/NiAl/Ti/Au, Ti/NiAl/Ni/Au, Ti/NiAl/Cr/Au.

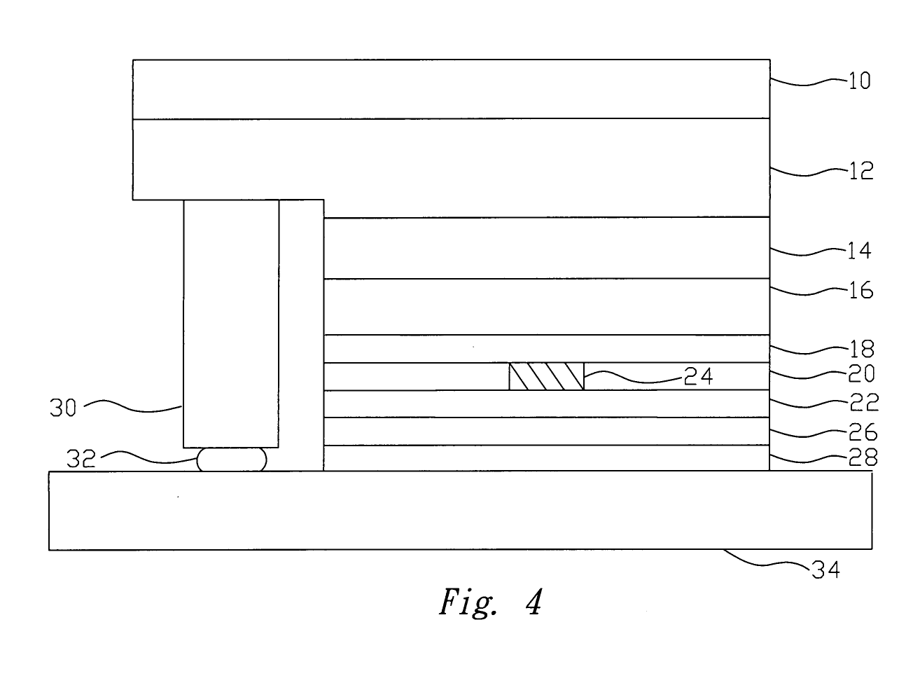

In addition, refer to FIG. 4, after disposing a first metal bonding layer 28 over the protective diffusion layer 26, a second metal bonding layer 32 over the first electrode 30, the LED chip of the present invention is flipped over and placed face down by flip-chip technology so as to make the first metal bonding layer 28 and the second metal bonding layer 32 connect with top surface of a thermal conductive substrate 34. The first metal bonding layer 28 as well as the second metal bonding layer 32 is made from gold, indium, or tin (Sn) while the thermal conductive substrate 34 is made from conductive material such as gold, silver, or aluminum. Moreover, the LED chip according to the present invention is bonded with the thermal thermal conductive substrate 34 so that the heat dissipation efficiency and conductivity of the LED are improved.

The difference between the present invention and the prior art is that there is a second electrode. The transparent conductive layer 18, the oxide layer 20, the reflective metal layer 22, and the protective diffusion layer 26 can be used as the second electrode-positive electrode. Thereby, the thermal thermal conductive substrate 34 conducts the negative electrode and the positive electrode so as to make the LED emit light.

In summary, the present invention provides a flip-chip light emitting diode with high light-emitting efficiency that reflects light from the light-emitting diode by combinations of the transparent conductive layer, the oxide layer, the reflective metal layer, the conductive layer, and the protective diffusion layer so as to prevent shielding of the LED light and increase the light-emitting efficiency effectively.

Moreover, the flip-chip light emitting diode in accordance with the present invention can be applied to lamp type LED, PCB type LED, top view LED, side view LED or SMD (surface mounting device) LED so as to have higher light-emitting efficiency.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalents.

What is claimed is:

1. A flip-chip light emitting diode with high light-emitting efficiency comprising:
a transparent substrate;
a semiconductor stacked layer disposed over the transparent substrate and having a n-type semiconductor layer, a light emitting layer and a p-type semiconductor layer while the light emitting layer is located between the n-type semiconductor layer and the p-type semiconductor layer;
a transparent conductive layer arranged over and electrically connected with the p-type semiconductor layer;
an oxide layer disposed over the transparent conductive layer;
a reflective metal layer set over the oxide layer;
a conductive layer mounted on the oxide layer for electrically connecting the transparent conductive layer with the reflective metal layer; a protective diffusion layer arranged over and electrically connected with the reflective metal layer;
a first electrode disposed over and electrically connected with the n-type semiconductor layer of the semiconductor stacked layer; and
a thermal conductive substrate with a first metal bonding layer and a second metal bonding layer on surface thereof;
wherein the first electrode and the protective diffusion layer face toward the thermal conductive substrate and connect with the first metal bonding layer and the second metal bonding layer respectively.

2. The flip-chip light emitting diode with high light-emitting efficiency as claimed in claim 1, wherein the thermal conductive substrate is made from gold, silver, or aluminum, copper, graphite, or alloy or compounds of above elements.

3. The flip-chip light emitting diode with high light-emitting efficiency as claimed in claim 1, wherein the transparent conductive layer, the oxide layer, the reflective metal layer, and the protective diffusion layer are able to be used as a second electrode.

4. The flip-chip light emitting diode with high light-emitting efficiency as claimed in claim 1, wherein the transparent substrate is made from sapphire, silicon carbide (SiC), zinc oxide (ZnO), gallium phosphide (GaP), or gallium arsenide (GaAs).

5. The flip-chip light emitting diode with high light-emitting efficiency as claimed in claim 1, wherein the n-type semiconductor layer is a n-GaN layer.

6. The flip-chip light emitting diode with high light-emitting efficiency as claimed in claim 1, wherein the light emitting layer is InGaN/GaN multiple quantum well structure or III-V semiconductor quantum well structures.

7. The flip-chip light emitting diode with high light-emitting efficiency as claimed in claim 6, wherein the semiconductor quantum well structures include AlₐIn_{b}Ga_{1-a-b}N/AlₓIn_{y}Ga_{1-x-y}N, wherein a,b≧0 ; 0≦a+b<1 ; x,y≧0 ; 0≦x+y<1 ; x>c>a.

8. The flip-chip light emitting diode with high light-emitting efficiency as claimed in claim 1, wherein the p-type semiconductor layer is a p-GaN layer.

9. The flip-chip light emitting diode with high light-emitting efficiency as claimed in claim 1, wherein the first electrode is selected from Ti/Al, Ti/Al/Ti/Au, Ti/Al/Pt/Au, Ti/Al/Ni/Au, Ti/Al/Pd/Au, Ti/Al/Cr/Au, Ti/Al/Co/Au, Cr/Al/Cr/Au, Cr/Al/Pt/Au, Cr/Al/Pd/Au, Cr/Al/Ti/Au, Cr/Al/Co/Au, Cr/Al/Ni/Au, Pd/Al/Ti/Au, Pd/Al/Pt/Au, Pd/Al/Ni/Au, Pd/Al/Pd/Au, Pd/Al/Cr/Au, Pd/Al/Co/Au, Nd/Al/Pt/Au, Nd/Al/Ti/Au, Nd/Al/Ni/Au, Nd/Al/Cr/Au, Nd/Al/Co/Au, Hf/Al/Ti/Au, Hf/Al/Pt/Au, Hf/Al/Ni/Au, Hf/Al/Pd/Au, Hf/Al/Cr/Au, Hf/Al/Co/Au, Zr/AI/Ti/Au, Zr/Al/Pt/Au, Zr/Al/Ni/Au, Zr/Al/Pd/Au, Zr/Al/Cr/Au, Zr/Al/Co/Au, TiNₓ/Ti/Au, TiNₓ/Pt/Au, TiNₓ/Ni/Au, TiNₓ/Pd/Au, TiNₓ/Cr/Au, TiNₓ/Co/Au, TiWNₓ/Ti/Au, TiWNₓ/Pt/Au, TiWNₓ/Ni/Au, TiWNₓ/Pd/Au, TiWNₓ/Cr/Au, TiWNₓ/Co/Au, NiAl/Pt/Au, NiAl/Cr/Au, NiAl/Ni/Au, NiAl/Ti/Au, Ti/NiAl/Pt/Au, Ti/NiAl/Ti/Au, Ti/NiAI/Ni/Au or Ti/NiAl/Cr/Au.

10. The flip-chip light emitting diode with high light-emitting efficiency as claimed in claim 1, wherein the transparent conductive layer is made from indium oxide, tin oxide, indium molybdenum oxide, indium cerium oxide, zinc oxide, indium zinc oxide (IZO), magnesium zinc oxide, tin cadmium oxide, or indium tin oxide (ITO), nickel oxide, platinum, nickel-gold(Ni/Au), titanium nitride(TiN), tantalum nitride(TaN), CuAlO₂, LaCuOS, CuGaO₂, SrCu₂O₂, iridium oxide(IrO), rhodium oxide(RhO), or ruthenium oxide/gold(RuO/Au).

11. The flip-chip light emitting diode with high light-emitting efficiency as claimed in claim 1, wherein the oxide layer is made from silicon dioxide(SiO₂), silicon nitride(Si₃N₄), silicon oxynitride (SiON), aluminum oxide (Al₂O₃), zinc oxide (ZnO), aluminum nitride (AlN) or beryllium nitride (BeN).

12. The flip-chip light emitting diode with high light-emitting efficiency as claimed in claim 1, wherein the reflective metal layer is made from gold(Au), aluminum(Al), silver(Ag), or rhodium(Rh).

13. The flip-chip light emitting diode with high light-emitting efficiency as claimed in claim 1, wherein the protective diffusion layer is made from Ti/Ni, Cr/Ni, TiN, TiW, wolfram, nickel, chromium, molybdenum, palladium, platinum, or combinations of above elements.

14. The flip-chip light emitting diode with high light-emitting efficiency as claimed in claim 1, wherein the first metal bonding layer is made from gold, indium, or tin.

15. The flip-chip light emitting diode with high light-emitting efficiency as claimed in claim 1, wherein the second metal bonding layer is made from gold, indium, or tin.
